(19) United States
(12) Patent Application Publication
(10) Pub. No.: US 2025/0334642 A1
(43) Pub. Date: Oct. 30, 2025

(54) Systems and Methods for Single-Cell Monitoring and Control

(71) Applicant: RJ1 Holdings Inc., San Antonio, TX (US)

(72) Inventor: Robert Milliken, San Antonio, TX (US)

(21) Appl. No.: 19/194,192

(22) Filed: Apr. 30, 2025

Related U.S. Application Data
(60) Provisional application No. 63/640,545, filed on Apr. 30, 2024.
(60) Provisional application No. 63/658,037, filed on Jun. 10, 2024.
(60) Provisional application No. 63/671,374, filed on Jul. 15, 2024.

(51) Int. Cl. G01R 31/389; G01B 21/32; G01R 31/3842; G01R 31/396; H01M 10/42; H01M 10/48; H01M 50/51

(52) U.S. Cl. CPC G01R 31/389; G01B 21/32; G01R 31/3842; G01R 31/396; H01M 10/425; H01M 10/482; H01M 50/51; H01M 2010/4271

(57) ABSTRACT

A battery system is provided having control, diagnostic, and safety features implemented at the battery cell level. By selectively bypassing one or more battery cells, a battery pack may function as a half-wave generator that produces a half-sine wave output voltage that can be converted into an alternating current using switching circuitry. Moreover, by applying a mixed signal to an individual battery cell, electrochemical impedance spectroscopy can be implemented without the need for bulky external equipment. Further still, safety features, such as battery strain sensors, may be implemented at the battery cell level to provide improved safety information.

### CROSS-REFERENCE TO RELATED APPLICATIONS

This application claims the benefit of U.S. Provisional Applications Nos. 63/640,545 filed Apr. 30, 2024, 63/658,037 filed Jun. 10, 2024, and 63/671,374 filed Jul. 15, 2024. The entirety of each of the priority applications is incorporated herein by reference.

### TECHNICAL FIELD

The subject matter described herein generally relates to systems and methods to be incorporated into energy storage systems. More specifically, the subject matter herein relates to energy storage systems, such as batteries.

### BACKGROUND

Renewable energy sources such as solar energy and wind power, essential in combating climate change, depend heavily on battery technologies in many instances. Such energy storage systems (ESSs) are central to ensuring a stable and resilient power supply from intermittent renewable sources. However, such energy storage systems often face safety, performance, and flexibility concerns.

One example that is enabling the sustainable transition to renewable resources is electric vehicles (EVs), which have emerged as a prime solution to address one of the largest sources of climate pollution. The technology associated with energy storage systems, such as batteries, has become a cornerstone of electrification of transportation and hundreds of billions of dollars have been put into battery chemistry related research and development. Yet, instances of battery fires and EV recalls continue to cast a spotlight on suboptimal safety and performance issues in the industry.

A key part of the safety, performance, and flexibility of these various energy storage systems are the subsystems that provide management and control. For example, Battery Management Systems (BMSs) are critical components in modern energy storage and electric vehicle systems, playing a pivotal role in ensuring the optimal performance, safety, and longevity of rechargeable batteries. At its core, a BMS is an electronic system that monitors and manages the key parameters of a battery pack, and by continuously collecting and analyzing data from the cells within the battery, the BMS can, for example, make real-time decisions to balance the charge among cells, prevent overcharging or over-discharging, and regulate temperature to avoid thermal issues.

### SUMMARY

The subject matter described herein addresses many of the disadvantages associated with prior battery pack systems by providing control, testing, and safety monitoring directly at the battery cell level, instead of the battery pack level. For example, unlike prior battery pack systems that simultaneously process information from numerous battery cells and control all of those energy storage cells from a system level (e.g., a single BMS unit, global switching circuitry, etc.), in some aspects, the systems and methods described herein provide components associated with each individual cell (e.g., cell-level switching circuitry, electrochemical impedance spectroscopy, strain sensors) that provide unique advantages. As one example, through the controlled connection or bypass of individual cells, a battery pack may function as a battery half-wave generator that can be used to directly generate alternating current via switching circuitry. Similarly, an electrochemical impedance spectroscopy (EIS) controller can also be implemented at the cell level, thereby allowing for the monitoring of impedance and the state-of-health of a battery cell without the need for large external testing equipment. Further still, by placing strain sensors directly at the cell level, more-accurate monitoring can be achieved and implementation times of safety measures may be reduced. Other advantages associated with the improved cell control, performance, and recognition of safety events are also disclosed herein.

In one aspect, the present disclosure provides a battery system for generating alternating current. The battery system may include a battery half-wave generator configured to produce a half-sine wave signal in an output voltage as well as switching circuitry in electrical communication with the battery half-wave generator. The switching circuitry may be configured to receive the half-sine wave output voltage and to produce a sine wave output voltage.

In another aspect, the present disclosure provides a method of measuring impedance through electrochemical impedance spectroscopy. The method may include generating a mixed frequency signal having both alternating current and direct current components and stimulating a battery cell by applying the mixed frequency signal at different frequencies. The method may also include measuring the terminal voltage of the battery cell and the injected current and determining the impedance by removing the direct current portion of the terminal voltage and dividing the resulting alternating current terminal voltage by the injected current.

In yet another aspect, the present disclosure provides a battery system with safety features for monitoring pressure changes. The battery system may include a first battery cell in a battery pack and a first strain sensor coupled to the first battery cell and configured to measure deformation of the first battery cell. The battery system may also include a second battery cell in the battery pack and a second strain sensor coupled to the second battery cell and configured to measure deformation of the second battery cell.

In one aspect, the present disclosure provides a battery system configured for maximum power point tracking. The system may include a battery pack having a plurality of battery cells, wherein each of the plurality of battery cells is configured to be controllably disconnected. The system may further include a battery management system in electrical communication with at least one of the battery packs. The battery management system may be configured to receive an output signal from an external device (e.g., solar panel), determine a target resistance to obtain a maximum power output from the external device, and modify the connection of at least one of the plurality of battery cells in the battery pack, such that the resistance provided by the battery pack about equals the target resistance.

The details of one or more variations of the subject matter described herein are set forth in the accompanying drawings and the description below. Other features and advantages of the subject matter described herein will be apparent from the description and drawings, and from the claims.

### DESCRIPTION OF DRAWINGS

FIG. 1A illustrates a battery system capable of generating alternating current using a battery half-wave generator. The switching circuitry is shown in a first configuration, with switches S2 and S3 open.

FIG. 1B illustrates the battery system of FIG. 1A in a second configuration with switches S1 and S4 open.

FIG. 2 illustrates a method of generating a sine wave output voltage using a battery half-wave generator.

FIG. 3 illustrates an example battery cell construction that may be used to build a composite battery half-wave generator.

FIG. 4 illustrates various cell unit states that each of the battery cells in FIG. 3 may be controlled to operate at.

FIG. 5 illustrates an example battery half-wave generator output, approximating a half-sine waves signal.

FIG. 6A illustrates a single battery cell being controlled via a single-cell battery management system.

FIG. 6B illustrates a single battery cell being controlled via a system-level battery management system.

FIG. 7A illustrates switching circuitry using TRIACs and an associated AC commutator controller for converting a half-sine wave output voltage to a sine-wave output voltage.

FIG. 7B illustrates switching circuitry using metal-oxide-semiconductor field-effect transistors (MOSFETs) and an associated AC commutator controller for converting a half-sine wave output voltage to a sine-wave output voltage.

FIG. 8 illustrates a system using a battery system controlled to provide maximum power point tracking to a solar panel.

FIG. 9 illustrates a battery system with an EIS controller for measuring the impedance of a battery cell.

FIG. 10 illustrates a method of measuring impedance through electrochemical impedance spectroscopy.

FIG. 11 illustrates a mixed current stimulus signal with wave shaping that may be used for electrochemical impedance spectroscopy.

FIG. 12 illustrates a circuit for compensating for a direct current portion of a mixed current signal used as a stimulus for electrochemical impedance spectroscopy.

FIG. 13 illustrates an example of electrochemical impedance spectroscopy results, including results related to the direct current portion of a mixed current signal.

FIG. 14 illustrates cell deformation associated with a single energy storage cell (e.g., a battery cell).

FIG. 15 illustrates an energy storage cell strain sensor configuration, with strain sensors having been placed on three different geometric surfaces of the energy storage cell.

FIG. 16 illustrates a battery cell strain sensor configuration, with a strain sensor coupled to terminals of the battery cell.

FIG. 17 illustrates a battery cell strain sensor configuration, with the strain sensor placed within an enclosure of the battery cell.

FIG. 18 illustrates a method of producing a control signal based on a measurement of a strain sensor coupled to an individual battery cell.

FIG. 19 illustrates an example chart depicting the strain magnitude from a strain sensor coupled to an individual battery cell.

FIG. 20 illustrates a section of a battery system, including a battery cell and an associated battery management system, in accordance with one aspect of the present disclosure.

The current subject matter will be better understood by reference to the following detailed description when considered in combination with the accompanying drawings which form part of the present specification.

### DETAILED DESCRIPTION

As used herein, “battery pack” may generally refer to at least two battery cells electrically connected in a series, parallel, or a mixture of both, unless context dictates otherwise. The individual battery cells may be connected using a battery pack circuit that may be in electrical connection with, and configured to provide power to, a device (e.g., an electric vehicle). As used herein, “battery circuit” may generally refer to a single battery cell electrically connected with a single battery management system, unless context dictates otherwise. Accordingly, a “battery pack” as used herein may include multiple battery cells in electrical connection with one another, with each battery cell potentially being a part of its own individual battery circuit with an associated battery management system.

As explained above, many commercial energy systems, such as batteries, rely on sensors and management systems for safety and control. Such monitoring and control is typically carried out at a system or “pack” level, with long wire connections between a single central processing unit and the individual battery cells. In other words, the BMS functions as a central hub, providing monitoring and control of all of the battery cells simultaneously. The present disclosure recognizes that sophisticated monitoring and control at a cellular level (e.g., a battery cell), instead of the system level, can be used to provide various improvements, including new device functionality, cell level impedance and state-of-health tracking, and improved safety monitoring.

While the systems and methods described herein are primarily discussed as examples of battery management systems, it should readily be appreciated that the teachings described herein can be applied to any suitable energy storage system, including, but not limited to, capacitors, supercapacitors, fuel cells, as well as other energy systems that may benefit from localized control of the energy cells in use. Furthermore, it should also be appreciated that the systems and methods of the present disclosure allow for various combinations of these energy storage systems (e.g., a supercapacitor in circuit with a battery cell). Batteries as described herein may be implemented using a variety of technologies and complementary hardware and software, including those described in the following pages, incorporated by reference in their entirety herein.

As one example application of control at the cell level, the present disclosure allows for a battery pack to function as a half-wave generator that can be used to directly produce AC current, without the need for traditional components associated with DC-AC conversion. Although batteries are generally used to generate DC power, there are many applications that require AC power. These applications include driving motors, solenoids, and pumps, as well as returning energy back to the grid. The systems and methods described herein augment and/or construct a battery pack that can produce an AC power output to drive AC powered applications. By inherently including the inverter functionality in the battery pack, these techniques can replace the need for large and costly DC to AC inverters that are typically needed to connect the DC battery to the AC application. The AC battery system described herein also allows for the optimization of the state-of-health of each battery cell by balancing thermal properties of the battery pack and minimizing the impacts of cell aging. As a result, the AC battery pack described in some aspects of the present disclosure may reduce the overall weight, cost, and size of AC applications that run from batteries.

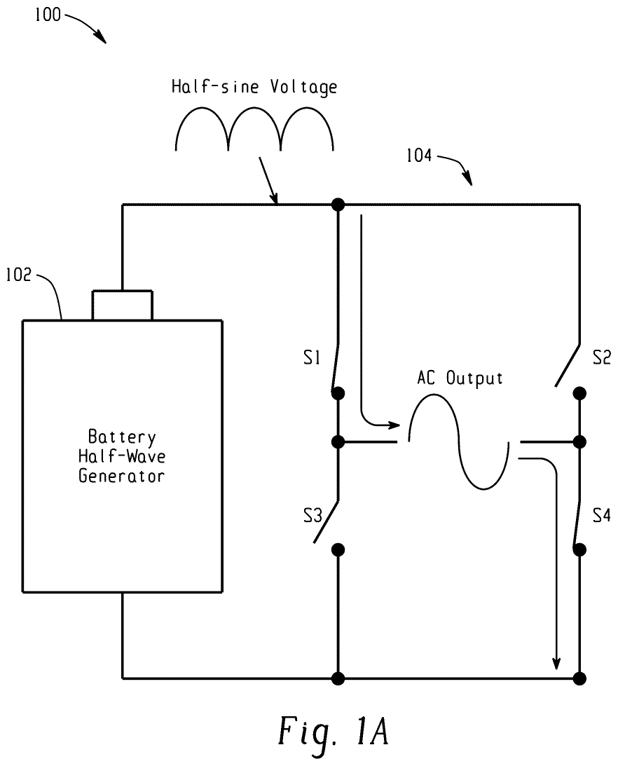

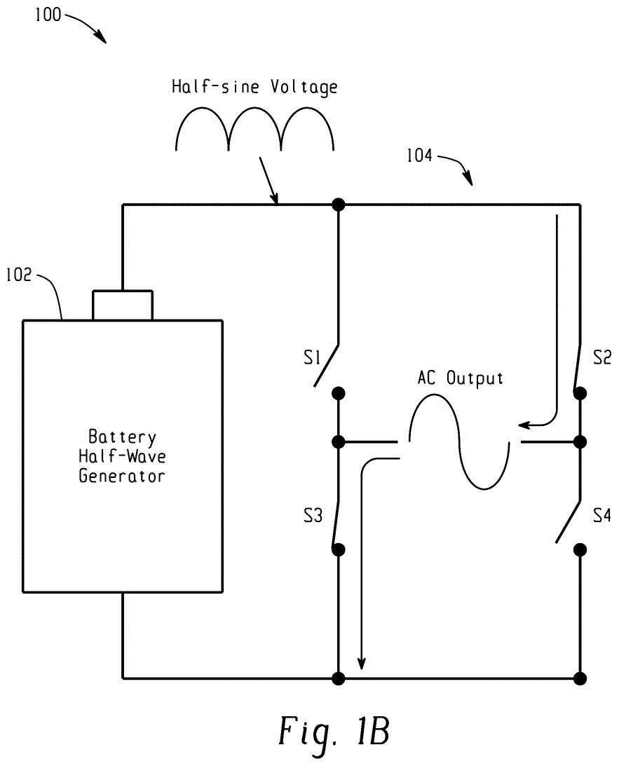

FIGS. 1A-1B depict a battery system 100 capable of generating alternating current using a battery half-wave generator 102. As will be further described, the battery half-wave generator 102 may include a plurality of battery cells that may be selectively connected or bypassed in order to produce a resulting half-sine voltage. This half-sine voltage may then be provided to simple switching circuitry 104 (also referred to herein as the commutator) that may convert the half sine voltage into a full sine output voltage that may be used for AC applications. Accordingly, the depicted example AC battery relies on the battery half-wave generator 102 to generate a pseudo half-sine wave from the battery pack and the switching circuitry 104, depicted as an H-bridge commutator with four switches (S1, S2, S3, and S4), may convert the half-wave output into a full sine wave output or AC output.

As shown, the switching circuitry 104, which is in electrical communication with the battery half-wave generator, may alternate between a first configuration (FIG. 1A) and second configuration (FIG. 1B) to produce the full sine output voltage. These configurations may correspond to two time periods for the switching circuitry 104, period 1 and period 2. During period 1, switches S1 and S4 may close and the battery half-wave generator output may be applied to the AC output terminals in the positive direction. Once the battery half-wage generator output voltage reaches zero, switches S1 and S4 may turn off and switches S2 and S3 turn on. The next battery half-sine wave may then be applied to the AC output terminals but in the negative direction. The cycle may then repeat, with the following half-sine wave reverting back to period 1. The switching circuitry 104 may toggle between these two states continuously, generating an AC power source.

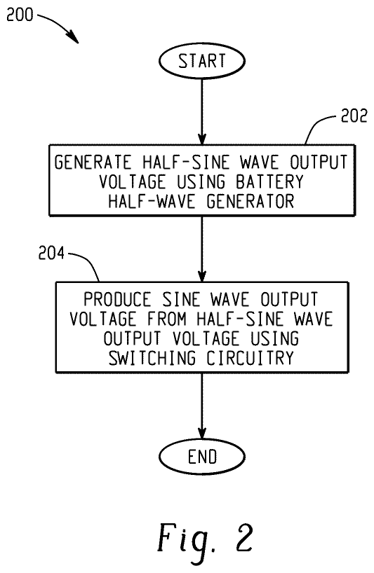

In accordance with the battery system 100 depicted in FIGS. 1A-1B, FIG. 2 depicts a method of generating a sine wave output voltage using a battery half-wave generator. At 202, a half-sine wave output voltage may be generated using a battery half-wave generator. Then, at 204, a sine wave output voltage may be produced from the half-sine wave output voltage using switching circuitry.

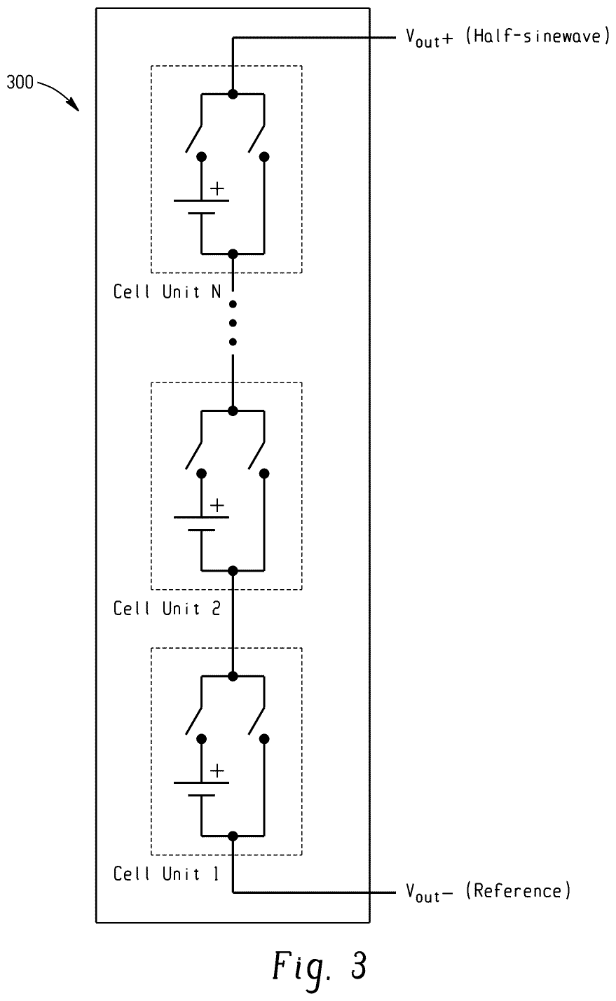

FIG. 3 depicts an example battery cell construction 300 that may be used to build a composite battery half-wave generator. As shown, a plurality of battery cells may be connected in series (e.g., Cell Unit 1, Cell Unit 2 . . . Cell Unit N) and may each include battery cell switches that allow the individual battery cells to be either connected or disconnected. A controller, either at the system level or a plurality of cell-level controllers, may be configured to controllably connect or bypass each battery cell in order to produce the half-sine wave in the output voltage of the battery pack. As shown, each of the plurality of battery cell units may include a cell switch configured to control the electrical connection between the first battery cell and the battery pack. Each battery cell unit may also include a bypass switch configured to control the electrical connection on an electrical pathway of the battery pack bypassing a given battery cell. The plurality of batteries may have a sufficient number of battery cells such that a half-sine wave may be accurately produced, and may include at least four battery cells, at least eight battery cells, or specifically at least fifteen battery cells.

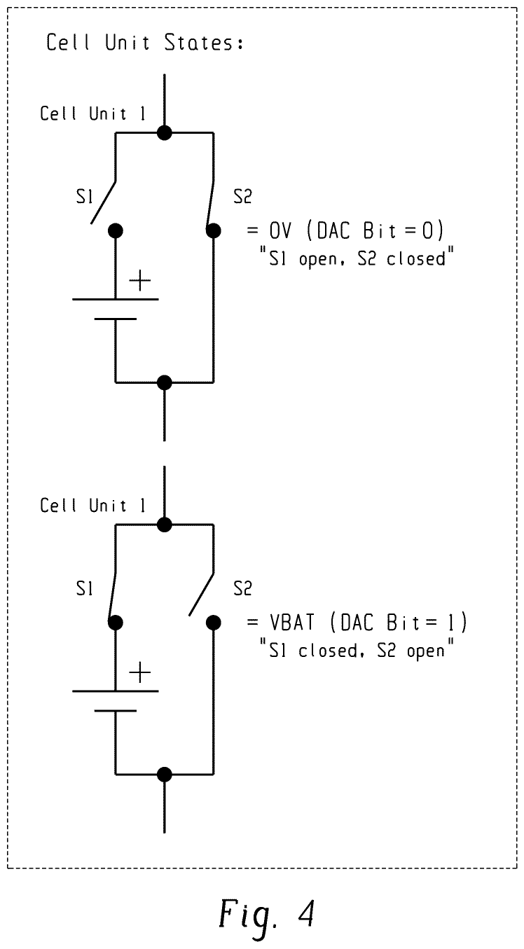

FIG. 4 depicts various cell unit states for that each of the battery cells in FIG. 3 may be controlled to operate at. As shown, a battery cell unit may be disconnected and thereby provide zero volts by opening cell switch (S1) and closing bypass switch (S2). Alternatively, a battery cell unit may be connected and thereby add its cell voltage (V_{BAT}) to the pack by closing cell switch (S1) and opening bypass switch (S2). Any combination of cells can be connected or bypassed in this manner. Each cell can be thought of as a single bit of a power digital to analog converter (DAC), where the connected switches dictate if the output is a ‘0’ or a ‘1’. It should be appreciated that alternative cell level switching circuitry may be implemented, provided that the ability to selectively connect or disconnect each battery cell is retained.

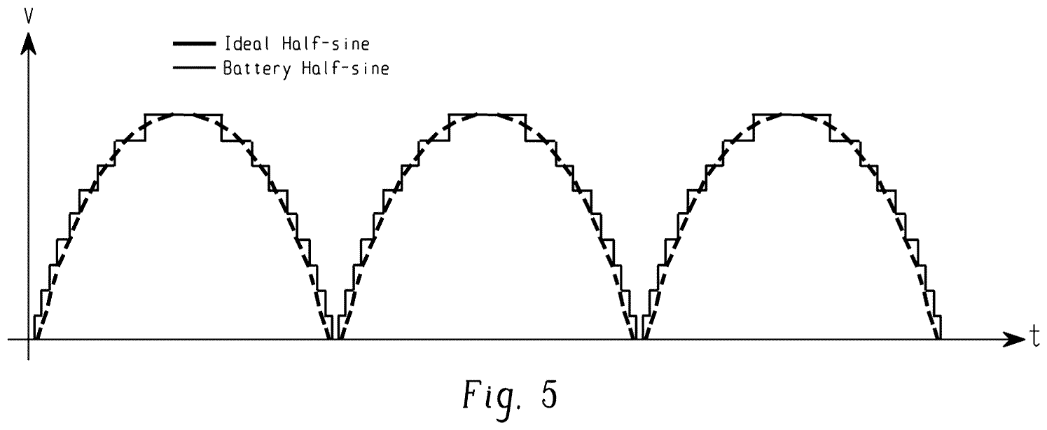

FIG. 5 depicts an example battery half-wave generator output, approximating a half-sine waves signal by controlling cell-level switches in a time sequence. The voltage of the battery half-sine wave (solid line) is depicted along with the ideal half-sine wave (dashed line) over time. As can be seen, the battery half-sine wave approximates the ideal half-sine wave by selectively activating additional individual battery cells within the pack, which produces a “stair-stepped” output voltage signal, with each individual step representing the connection or disconnection of a battery cell. As shown, the battery cell connection may be controlled such that each battery cell is activated after a different length of time, such that the ideal half-sine wave can be closely approximated. In other words, many battery cells may be rapidly connected or disconnected near the minimum point of the half-sine wave, while the time in between connection or disconnection may increase near the maximum of the half-sine wave.

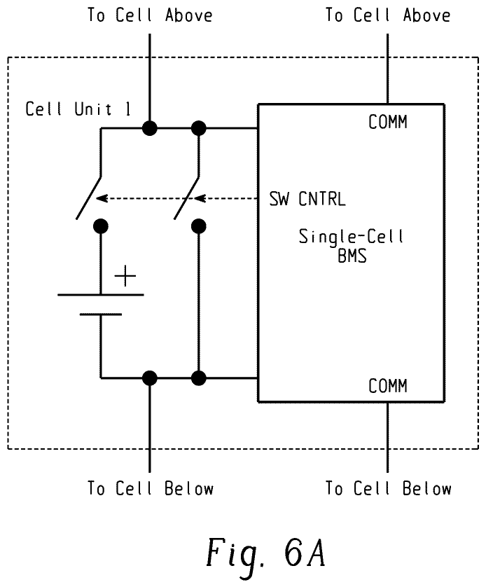

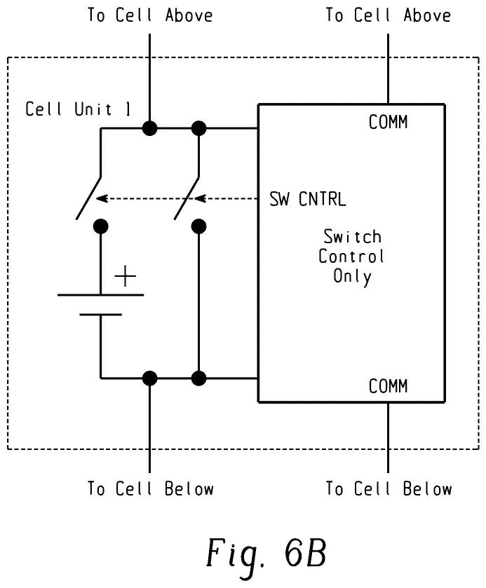

FIGS. 6A-6B illustrate a single battery cell being controlled via either a single-cell battery management system (FIG. 6A) or a system-level battery management system (FIG. 6B). In other words, the decision on which cells need to be turned off or on to generate the half-sine wave can either be done locally as in a distributed battery management system or at the pack level as a centralized BMS. Regardless of which control systems are implemented, the ability to turn on or off the connected switches at the battery cell level permit the generation of the half-sine wave. It should also be appreciated that which battery cell is activated for each section of the half-sine wave voltage may be controllably varied based on, for example, the order of the battery cells within the battery pack, the state-of-charge (SoC) of each battery cell, the state-of-health of each battery cell, as well as other factors. Furthermore, the battery cells may be cycled such that a first portion of the battery pack is used to generate the half-sine wave output voltage for a first period of time, while a second portion of battery cells may remain disconnected until a second period of time, at which the first portion may then remain disconnected.

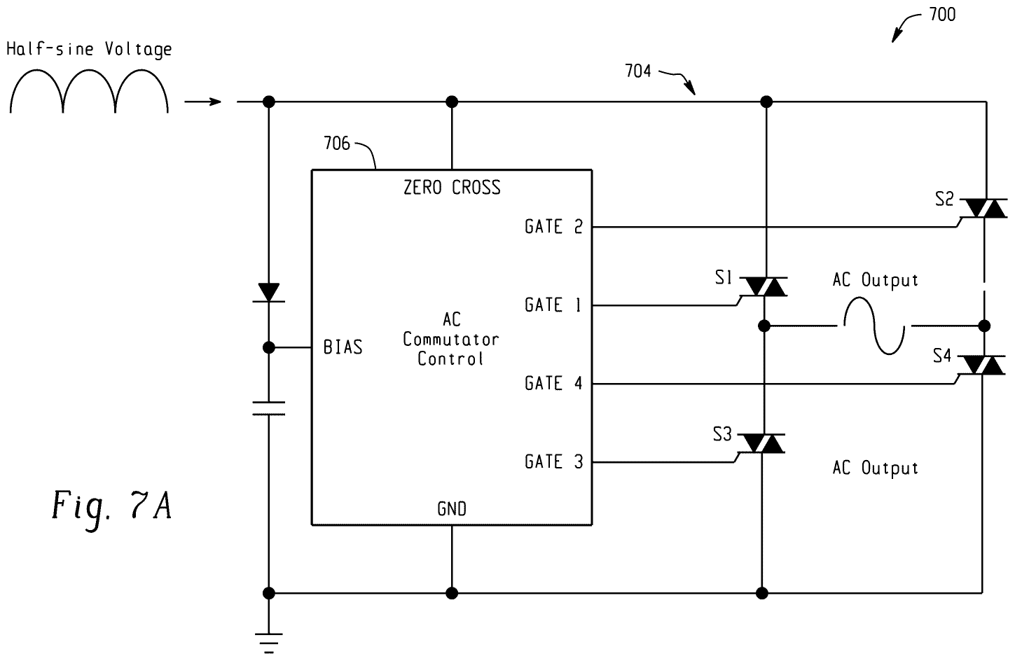

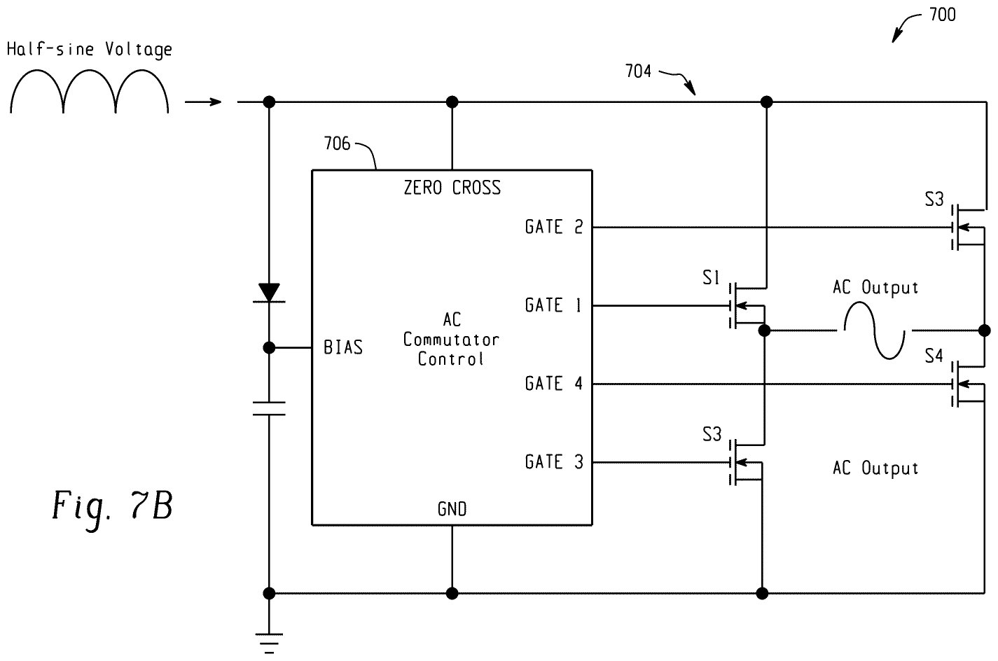

FIGS. 7A-7B illustrate a circuit 700 having various forms that the switching circuitry 704 (i.e., commutator) may take. For example, FIG. 7A relies on TRIACs for switches, while FIG. 7B relies on MOSFETS. Any suitable switch may be utilized, including, but not limited to, TRIACs, metal-oxide-semiconductor field-effect transistors (MOSFETs), insulated gate bipolar junction transistors (IGBJTs), bipolar junction transistors (BJTs), and/or any other thrystor. As shown, an AC commutator controller may be used to control the switches in the switching circuitry 704 in order to convert the half-sine wave output voltage to a sine wave output voltage. The bias may be sourced from the incoming half-sine voltage, as shown, and the decision to commutate the depicted H-bridge output switch structure may be determined by the input half-sine wave approaching 0V, as previously discussed.

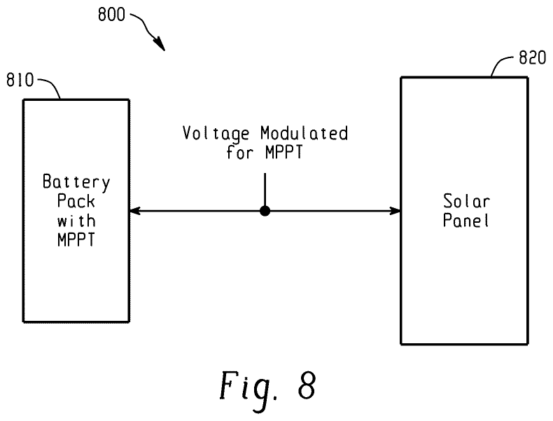

FIG. 8 depicts a system 800 in which using a battery pack 810 may be selectively controlled at a cell level in order to provide maximum power point tracking to a solar panel 820. Without being bound by theory, the efficiency of power transfer from the solar cell depends on the amount of available sunlight, and as these conditions vary, the load characteristic that gives the highest power transfer can also change. Accordingly, in order to keep power transfer from the solar panel 820 near peak efficiency, the load characteristic of the battery pack 810 may be altered using the cell-switching techniques previously described above. In this manner, by controllably connecting and disconnecting a portion of the battery cells, the load characteristic can be adjusted to match a change in the conditions of the solar panel 820, which may be monitored and provided to a controller of the battery pack. In other words, the current conditions of the solar panel 820 may be used to controllably connect and disconnect battery cells within the battery pack 810. Accordingly, the power extraction from the solar panel 820 may be maximized by optimizing the voltage output of the solar panel 820 when extracting current. Typically, an inverter is needed to level-shift the voltage between the connected battery and the solar panel. But by adding the maximum power point tracking into the control of the output of the battery pack 810, the inverter may not be needed since the battery output can directly track the voltage of the solar panel 820 that delivers maximum power. For example, if a solar panel's maximum power point is at 20 volts and 10 amps, the maximum power point tracking system would ensure the load is adjusted via battery cell switching to draw 20 volts and 10 amps from the panel, thereby maximizing the power output.

In another aspect, systems and methods described herein may provide cell level diagnostic and monitoring, including AC electrochemical impedance spectroscopy of a battery cell. Specifically, AC EIS may be achieved by allowing a DC biased AC signal such that the stimulus only needs a uni-direction source or sink. The DC bias may be measured and compensated in order to provide accurate AC EIS measurements. As will be further described, this technique may reduce overall complexity, thereby making cell-level EIS viable.

In general, battery state-of-health (SoH) is important to track and monitor for both safety and prolonging battery life. There are several methods that can be used for monitoring SoH, including voltage, current, cell temperature, cell pressure, and cell impedance. Generally, the more information and telemetry used, the more accurate the measurement of SoH will be. Impedance monitoring remains one of the more useful methods to determine the SoH since, without being bound by theory, this method can help determine the integrity and operation of the internal cell components, including the health of the anode, cathode, and separator. As the cell ages, impedance typically increases. This increase in impedance can lead to more heat generation (energy loss) and limits in power delivery. One method for measuring impedance is electrochemical impedance spectroscopy. EIS typically uses a small AC signal to perturb the cell under test. The AC signal can be injected by either a voltage (potentiostatic EIS) or current (galvanostatic EIS) applied to the cell terminal. The AC method provides a means to maintain the steady-state of the cell under test such that the energy within the cell is constant. Any DC component can cause the cell to change during test, potentially causing inaccuracies in the impedance measurement. Moreover, because certain cell internal structure and interfaces may have impedances that vary with frequency, the AC stimulus may be varied in frequency to map the cell over a large frequency range from, for example, sub hertz to upwards of 100 kHz. This impedance profile can shift and change as the cell ages or becomes damaged, and monitoring this change can determine the life of the cell and its performance. Previously, AC EIS was generally performed using large, specialized bench test equipment. The AC signal used in EIS may utilize a bidirectional supply that can both source and sink current and thus provide a way to inject energy back into the cell during positive half-cycles. In some forms, another cell may be used for this via a bidirectional power converter or a pack-level converter.

The present disclosure recognizes that it is desirable to perform AC EIS in-situ within the pack or cell by allowing a DC Biased AC signal such that the stimulus only requires a uni-direction source or sink. While adding a DC bias to the AC stimulus may cause the cell to change its state-of-charge, and the impedance of the cell changes with SoC, it is herein recognized that, if the change in SoC is kept small, the effects on the impedance measurement can be minimal. For this reason, in the techniques described herein, the in-situ testing duration may be kept to a minimum, on the order of, for example, a few minutes or less. The relative DC+AC mixed signal may also be reduced to minimize the SoC effect.

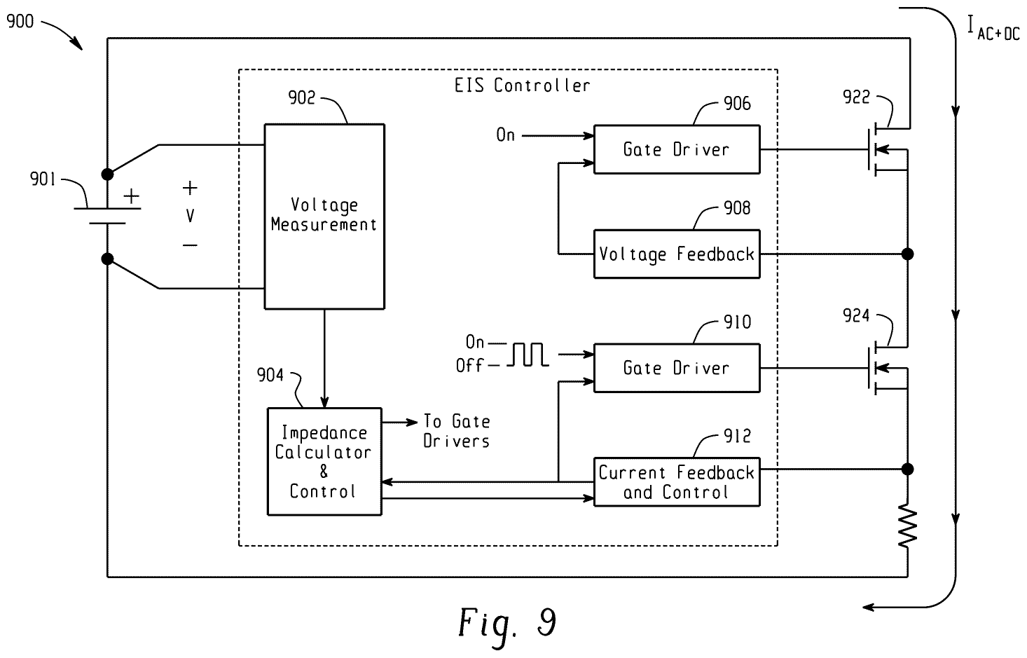

FIG. 9 depicts a battery system 900 with an EIS controller for measuring the impedance of a battery cell 901. As shown, a voltage sensor 902 may acquire a voltage measurement that may be provided to an impedance controller 904. The impedance controller may control MOSFETs 922, 924 via gate drivers 906, 910, such that the MOSFETs 922, 924 are driven to stimulate the cell 901 at different loading frequencies such that the stimulus has both AC and DC components. A voltage feedback sensor 908 and current feedback sensor 912 may be used to further control the MOSFETs, and may also be provided to the impedance controller in or to process and determine the impedance of the cell 901 at various frequencies. The MOSFETs 922, 924 have a low impedance in the on state and can vary significantly with temperature and from manufacturing specifications. As a result, the current injection can be difficult to control. In order to alleviate this issue and drastically improve the accuracy of the injection current in the on state, the current through the MOSFET 924 may be sensed and fed back into the gate driver 910, forming a current feedback loop. For example, when the current goes beyond a set threshold, the current feedback loop may command the gate driver 910 to lower the current through the MOSFET 924. Thus, a controlled current pulse may be generated and the level may be controlled by changing the sense threshold.

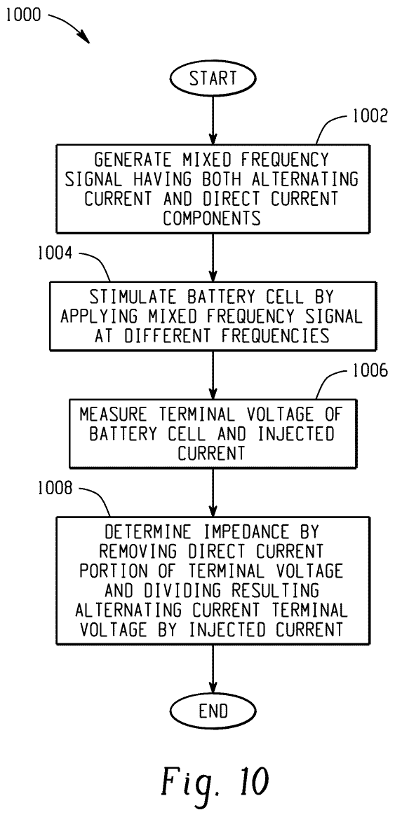

In accordance with the battery system 900 of FIG. 9, the method 1000 depicted in FIG. 10 depicts a technique for measuring impedance through electrochemical impedance spectroscopy. At 1002, a mixed frequency signal having both alternating current and direct current components may be generated. At 1004, a battery cell may be stimulated by applying the mixed frequency signal at different frequencies. While the present disclosure often provides example systems that use MOSFETs to inject the stimulus into the connected cell, it should be appreciated that other methods to inject a sink or source can be used, including the use of only a single MOSFET. Additionally or alternatively, the one or more MOSFETs may also be used for power path control of the battery cell, allowing the battery cell to be connected to the battery pack or isolated/disconnected from the battery pack. Thus, both power path and EIS functions may use the same circuitry and power devices, saving size, cost and complexity. At 1006, the terminal voltage of the battery cell and the injected current may both be measured. At 1008, the impedance may be determined by removing the direct current portion of the terminal voltage and dividing the resulting alternating current terminal voltage by the injected current.

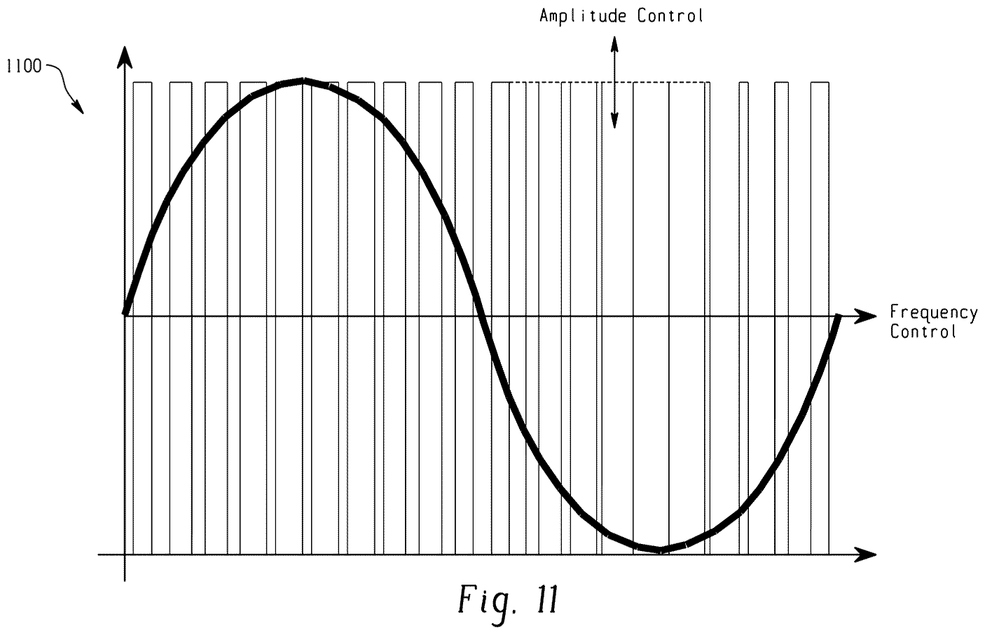

FIG. 11 depicts a mixed current stimulus signal with wave shaping that may be used for electrochemical impedance spectroscopy. As shown, amplitude control may be used to wave-shape the stimulus or be lowered for different battery cells. The frequency of the current pulses may also be controlled by the impedance controller. As discussed, the impedance can be measured at several different frequencies to measure the appropriate internal structure of the cell. The control of both the amplitude and frequency allows the DC-Bias EIS technique to be used on batteries with different capacity size or chemistries. This also allows wave-shaping the injected signal such that a pseudo sine wave or any other shape, when filtered, may be generated from a modulated square-wave.

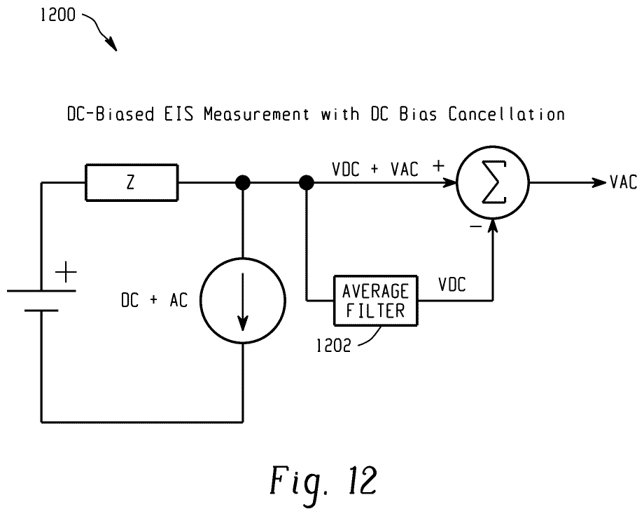

FIG. 12 depicts a circuit 1200 for compensating for a direct current portion of a mixed current signal used as a stimulus for electrochemical impedance spectroscopy. The DC portion of the stimulus may be compensated in order to extract the AC characteristics of the impedance, including both the magnitude and phase shift between the current stimulus and the resulting cell terminal voltage. As shown, the addition of a filter 1202 may be used to extract the average or moving average of the resulting terminal voltage signal. This filtered version may be subtracted from the overall mixed signal (AC+DC) stimulus to yield just the AC portion of the resulting terminal voltage. The resulting AC terminal voltage may then be divided by the AC portion of the injected current to yield the impedance at a given frequency.

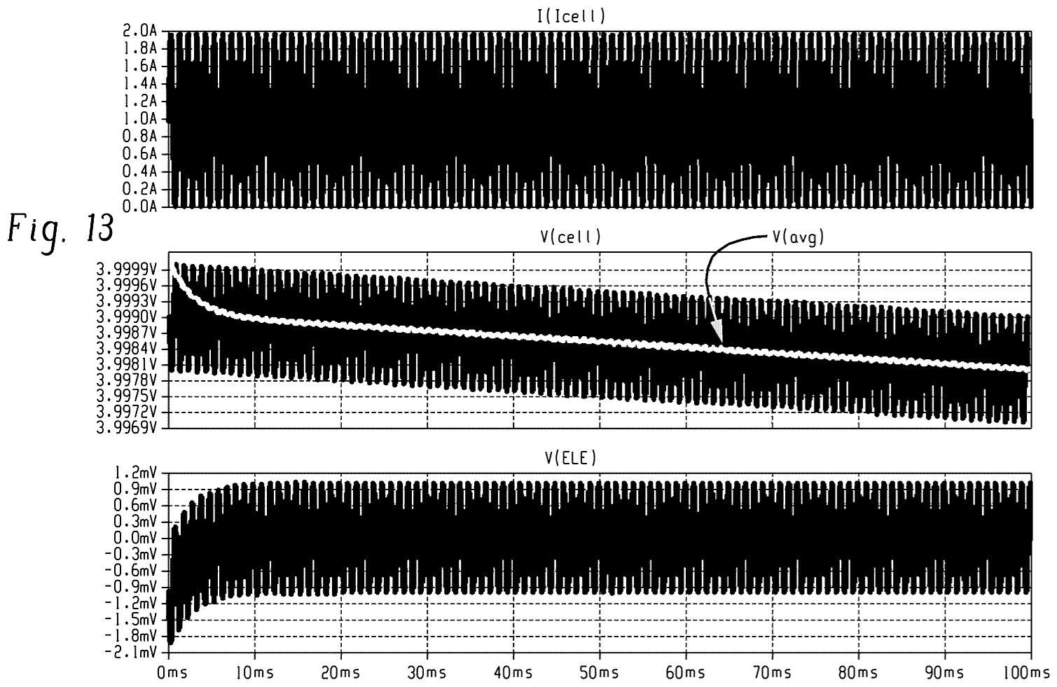

FIG. 13 depicts an example of electrochemical impedance spectroscopy results, including results related to the direct current portion of a mixed current signal. In this example, a 1 kHz test signal, I(Icell) (top column), was sourced from the connected cell. The terminal voltage, V(cell) (middle column), shows how the series cell impedance causes a fluctuation of the same frequency. As shown, the terminal voltage has a droop due to the DC component. As discussed, V(cell) may be filtered through, for example, a double pole RC filter with 15 Hz corner to yield V(avg) in FIG. 13. This average may then be subtracted from V(cell) to yield the AC-only response with no droop. The impedance of 1 m ohm using a 1 A peak-to-peak stimulus shows a resulting 1 mV peak-to-peak signal. These measurements may be done, for example, using an analog-to-digital converter (ADC), and the average can be done in a processor using digital signal processing (DSP). The least significant bit (LSB) of the ADC may be specifically smaller than the amplitude of the V(cell) AC portion to ensure an accurate reading. However, the absolute accuracy may not be needed for SoH tracking as long as the drift of the ADC readings can be minimized. Thus, relative changes may still be useful to show the aging of the cell and any damage to the cell.

In yet another aspect, the present disclosure provides implementations wherein one or more strain or pressure sensors may be coupled to an individual battery cell. As discussed, it can be desirable to track battery state-of-health for both safety and prolonging battery life. Pressure or strain caused by pressure within the cell is another useful parameter to determine the health of the cell. It can also provide a very fast method to determine an internal thermal runaway event. The measurement of the pressure or strain of the cell can be used to safeguard the cell, such as by removing the cell from the circuit or removing the environment or external stimuli that are causing the internal increase of pressure.

Prior attempts to utilize pressure or strain sensors in battery systems have often focused on placing such sensors within a sealed battery pack enclosure at a system level. However, such techniques may lack the sensitivity, and a lag between event and detection may be relatively slow. Moreover, for battery packs designed for control and monitoring at the system level, the only recourse upon detection of an event may often be to take an entire pack off line or shut down without the ability to determine the responsible cell. In such cases, the ability to prevent cell rupture may be quite limited.

Systems and methods herein may, in some implementations, place a pressure or strain sensor on a plurality of individual cells (e.g., each individual cell in a battery pack) to monitor and measure the amount of strain produced by the increase of internal gases and pressure. When increased pressure causes the electrodes and external case to flex and deform, that movement can be monitored by a strain sensor. In certain implementations, strain sensors can be integrated into battery backs without a case and can determine which cell or cells are exhibiting the high-pressure event.

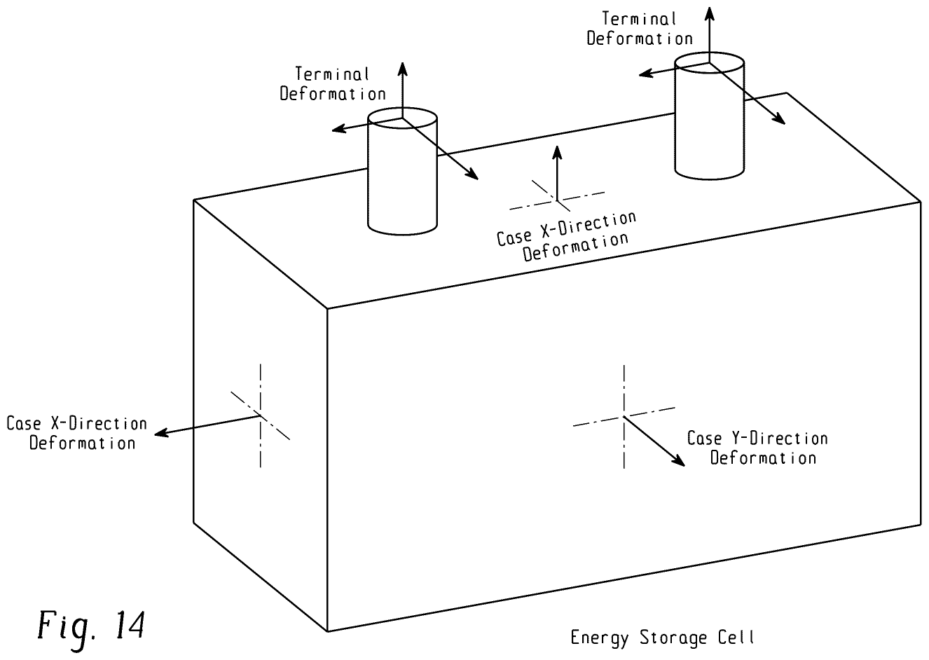

FIG. 14 depicts cell deformation associated with a single energy storage cell (e.g., a battery cell). As can be seen, under a high-pressure event, the case and/or electrodes of the energy storage cell may flex and deform. This strain may be exhibited in multiple geometric directions (e.g., x plane, y plane, z plane) on either the geometric surfaces of the battery cell enclosure or the terminals of the energy storage cell.

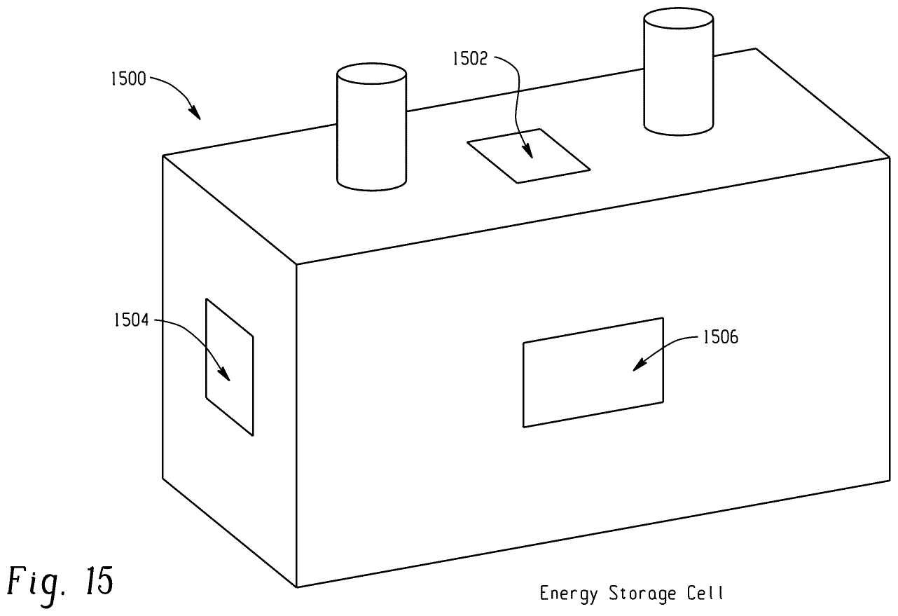

FIG. 15 depicts an energy storage cell 1500 having an individual strain sensor configuration, with strain sensors 1502, 1504, 1506 having been placed on three different geometric surfaces of the energy storage cell. As shown, the strain sensors 1502, 1504, 1506 may be positioned on outer surfaces of the energy storage cell 1500, such that a deformation in the outer surfaces of the case structure (i.e., enclosure) of the energy storage cell 1500 may be detected. As will be further described, a battery pack may include multiple energy storage cells, each having unique strain sensors, which may provide measurement signals to one or more battery management systems for processing and safety control. It should be appreciated that this is one example implementation, and the strain sensor(s) may be positioned at different locations around the energy storage cell 1500 on any of the surfaces that may deform. The number of strain sensors included may depend on the cell construction and specific internal cell interactions.

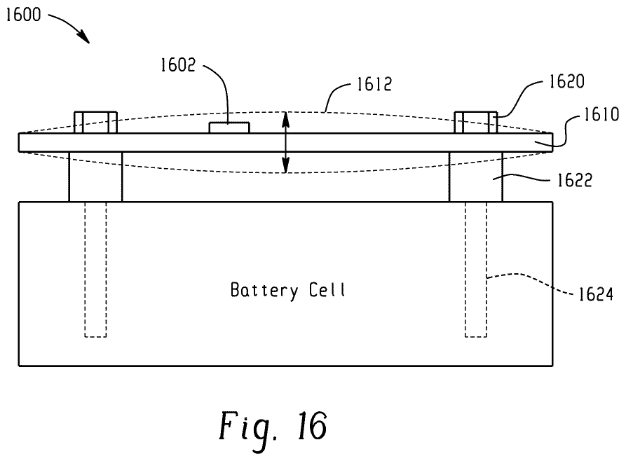

FIG. 16 depicts a battery cell 1600 having an alternative individual strain sensor configuration, with a strain sensor 1602 coupled to a printed circuit board (PCB) 1610 that contacts each terminal 1620 extending from each internal electrode 1624 of the battery cell 1600. A battery spacer 1622 may be positioned on each terminal 1620 between the PCB 1610 and the body of the battery cell 1600. Using this configuration, the strain from the deflections or deformation in the cell terminals 1620 may be measured. By placing the strain sensor 1602 on the printed circuit board 1612 or another substrate, the deformation of the terminals 1620 may be transferred to the PCB and subsequently measured. Alternatively, one or more strain sensors may be mechanically connected directly to one or both of the terminals.

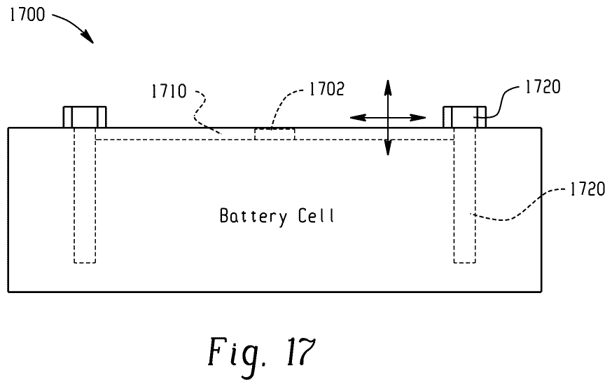

FIG. 17 depicts a battery cell 1700 with yet another individual strain sensor configuration, with the strain sensor 1702 placed within the enclosure of the battery cell 1700. The strain sensor 1702 is shown placed on a substrate 1710 coupled between each internal electrode 1720 of the battery cell 1700, with each internal electrode 1720 connected to an electrode 1720. As shown, deformation may be directly measured based on internal pressure and deformation occurring within the cell, such as a change in position of the internal electrodes or a contacted outer surface of the cell case structure.

The strain sensor described herein may be a standalone passive sensor, a standalone integrated circuit (IC), or a sensor integrated into another integrated circuit (IC) or system-on-chip. The IC or system-on-chip may be placed on a PCB, as shown, or coupled to or fully integrated into the cell during manufacturing. The strain sensor can provide analog, digital, or analog and digital data to a processing unit, such as a processor of a battery management system, that may then determine whether the cell is meeting specified safety level thresholds and SoH requirements. If not, the processor may determine a corrective action to be performed, such as providing a control signal to switching circuitry to disconnect one or more cells. This processor may reside at the cell level, with each cell having its own processor, or the processor may be centralized and take data from multiple cell sensors in a battery pack or system.

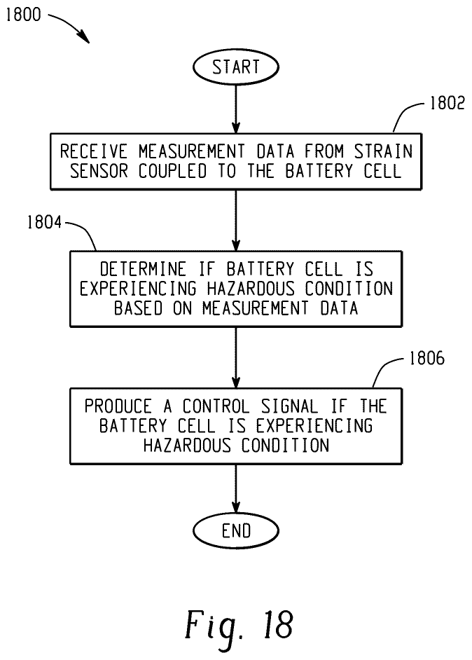

Consistent with FIGS. 14-17, the method 1800 depicted in FIG. 18 is a technique for producing a control signal based on a measurement of a strain sensor coupled to an individual battery cell. At 1802, measurement data may be received from a strain sensor coupled to a battery cell. The measurement data may be received by, for example, a processor of a battery management system or other control system associated with the battery cell. At 1804, whether the battery cell is experiencing a hazardous condition may be determined based on measurement data. This determination may be made by a processor using, for example, preset thresholds for strain deviations. At 1806, a control signal may be produced if the battery cell is experiencing a hazardous condition, such as a degassing event or thermal runaway. The control signal may be provided to, for example, switching circuitry, which may specifically disconnect one or more battery cells of a battery pack.

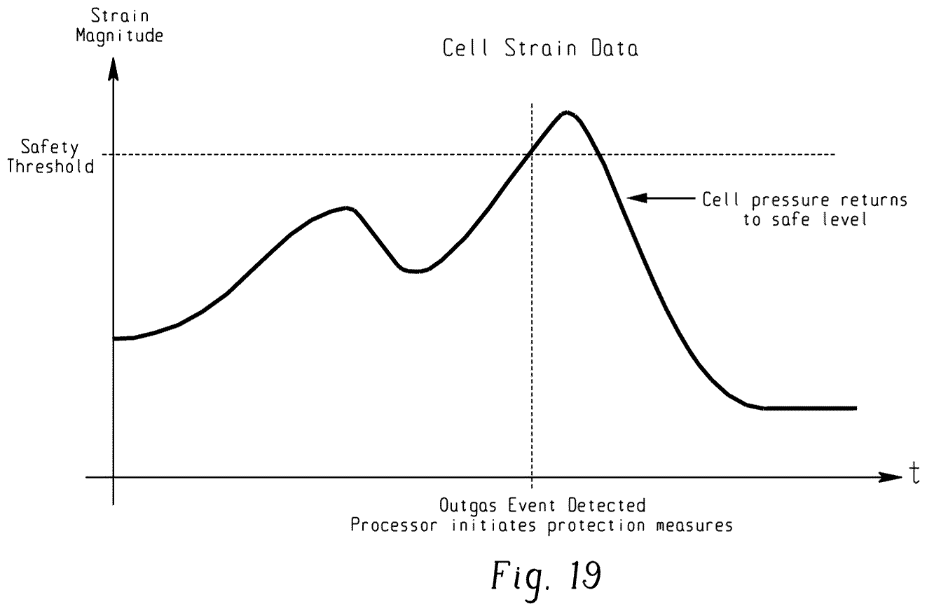

Consistent with this method, FIG. 19 depicts an example chart depicting the strain magnitude from a strain sensor coupled to an individual battery cell. The strain magnitude data may be received by a processor filtered internally and/or externally to provide a signal that can be used to determine the level of strain related to the internal pressure of the battery cell. A safety threshold level may be used to determine the safe operation of the cell being monitored. If the threshold is crossed, the cell processor may create a control signal and/or an alert signal, such as a signal that alerts the end user that an internal unsafe event is imminent or in process. Accordingly, protection measures may be initiated (e.g., disabling or disconnecting a cell) to return the cell to a safe operating level and prevent catastrophic damage, as shown.

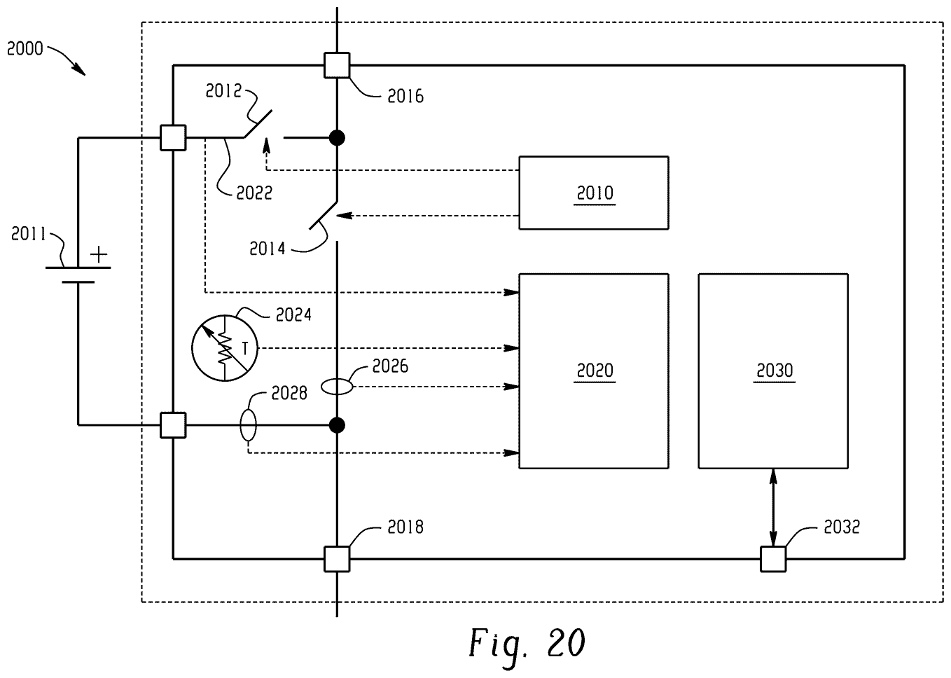

FIG. 20 depicts an example battery system that may be used to implement the techniques described herein. The example battery system includes a battery cell 2011 and an associated battery management system 2000 (contained within the dashed lines in this depiction). The battery management system 2000 may include a positive terminal 2016 and a negative terminal 2018 as part of the electrical circuit to which the battery cell 2011 may be connected to. The BMS 2000 may include various components, including, but not limited to, switching circuitry, which may include a switch controller 2010 configured to adjust a cell switch 2012 and a bypass switch 2014. The switching circuitry may be configured to safely connect, disconnect, bypass, short, and/or partially connect the battery cell during operation. A cell controller 2020 may be in electrical communication with the switch controller 2010 and configured to receive measurement data for the battery cell 2011. This data may be provided to the cell controller 2020 using a number of sensor components in addition to the strain sensors and other measurement sensors previously described. For example, as shown, a voltage sensor 2022, temperature sensor 2024, and multiple current sensors 2026, 2028 may all supply measurement data to the controller 2020 to permit active monitoring of the battery cell 2011. Among other advantages, the in-situ measurement (sensing) architecture of the BMS 2000 may provide better detection of the early signs of battery degradation and failure while increasing performance, reliability, and safety. The controller 2020 may be configured to process the first battery cell 2011 measurement data and to take certain actions depending on these inputs, including producing a control signal that may be provided to the switch controller 2010 in order to modify the state of switches 2012, 2014 (e.g., to open or close one switch, or both). The BMS may also include a bi-directional communication interface (BCI) 2030 in electrical communication with the cell controller 2020 and the switching circuitry. The BCI may be configured to provide and receive communication signals to other BMSs, to internal battery system components, or to external systems. In this depiction, the BCI 2030 may rely on a communication port 2032 when providing communication signals to other BMSs. Single cell BMS architectures and localized battery switching circuitry are described, for example, in U.S. Pat. App. Pub. No. 2024/0243371, the contents of which are herein incorporated by reference in their entirety.

It should be appreciated that the techniques described herein are applicable to energy systems beyond the various configurations described. For instance, an energy storage system may include multiple energy storage cells (e.g. supercapacitor, fuel cell, etc.) and multiple energy storage management systems (ESMSs) in electrical communication with each energy storage cell. The ESMSs may each incorporate any of the teachings described herein relating to the use of local, single-cell monitoring, testing, and control.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

In the event of inconsistent usages between this document and those documents so incorporated by reference, the usage in the incorporated reference(s) should be considered supplementary to that of this document; for irreconcilable inconsistencies, the usage in this document controls.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. Other implementations may be within the scope of the following claims.

What is claimed is:

1. A battery system for generating alternating current, the battery system comprising:
a battery half-wave generator configured to produce a half-sine wave signal in an output voltage; and
switching circuitry in electrical communication with the battery half-wave generator, the switching circuitry configured to receive the half-sine wave output voltage and to produce a sine wave output voltage.

2. The system of claim 1, wherein the battery halfwave generator includes:
a battery pack having a plurality of battery cells connected in series; and
a controller configured to controllably connect or bypass each battery cell in order to produce the half-sine wave in the output voltage of the battery pack.

3. The system of claim 2, wherein each of the plurality of battery cells includes:
a cell switch configured to control the electrical connection between the first battery cell and the battery pack; and
a bypass switch configured to control the electrical connection on an electrical pathway of the battery pack bypassing the first battery cell.

4. The system of claim 2, wherein each of the plurality of battery cells includes a battery management system having a controller configured to controllably connect or bypass each battery cell.

5. The system of claim 1, wherein the switching circuitry includes an H-bridge circuit.

6. The system of claim 1, wherein the switching circuitry includes a switch controller configured to modify the state of at least one switch of the switching circuitry when the half-sine wave output voltage equals about zero.

7. The system of claim 1, wherein the switching circuitry includes switches selected from the group consisting of TRIACs, metal-oxide-semiconductor field-effect transistors (MOSFETs), insulated gate bipolar junction transistors (IGBJTs), and bipolar junction transistors (BJTs).

8. The system of claim 1, wherein the battery half-wave generator includes a battery pack having at least four battery cells.

9. A method of measuring impedance through electrochemical impedance spectroscopy, the method comprising:
generating a mixed frequency signal having both alternating current and direct current components;
stimulating a battery cell by applying the mixed frequency signal at different frequencies;
measuring the terminal voltage of the battery cell and the injected current;
determining the impedance by removing the direct current portion of the terminal voltage and dividing the resulting alternating current terminal voltage by the injected current.

10. The method of claim 9, wherein removing the direct current portion of the terminal voltage includes extracting the moving average or moving average of the resulting terminal voltage signal using a filter.

11. The method of claim 9, wherein a metal-oxide-semiconductor field-effect transistor (MOSFET) is used to stimulate the battery cell.

12. The method of claim 11, wherein the measured injected current is used to modify the current through the MOSFET via a current feedback loop.

13. The method of claim 9, further comprising controlling the amplitude of the mixed frequency signal.

14. A battery system with safety features for monitoring pressure changes, the battery system comprising:
a first battery cell in a battery pack;
a first strain sensor coupled to the first battery cell and configured to measure deformation of the first battery cell;
a second battery cell in the battery pack; and
a second strain sensor coupled to the second battery cell and configured to measure deformation of the second battery cell.

15. The battery system of claim 14, further comprising:
a third strain sensor coupled to the first battery cell and configured to measure deformation of the first battery cell, wherein the third strain sensor is positioned on a different geometrical surface relative to the first strain sensor.

16. The battery system of claim 14, wherein the first strain sensor is coupled to a terminal of the first battery cell.

17. The battery system of claim 16, wherein the first strain sensor is coupled to both a positive and negative terminal of the first battery cell.

18. The battery system of claim 14, wherein the strain sensor is positioned on a printed circuit board.

19. The battery system of claim 14, wherein the first battery cell includes a housing and the first strain sensor is positioned within the housing of the first battery cell.

20. The battery system of claim 14, further comprising a first controller is configured to process measurement data received from the first strain sensor to determine if the first battery cell is experiencing a hazardous condition and to produce the control signal if the first battery cell is experiencing a hazardous condition.
